(19) United States
(12) Patent Application Publication
(10) Pub. No.: US 2026/0253629 A1
(43) Pub. Date: Aug. 27, 2026

(54) MEMORY DEVICES, OPERATION METHODS OF THE MEMORY DEVICES AND MEMORY SYSTEMS

(71) Applicant: Yangtze Memory Technologies Co., Ltd., Wuhan (CN)

(72) Inventors: Xiangyin Zhou, Wuhan (CN); Xiaodong Mei, Wuhan (CN); HuangPeng Zhang, Wuhan (CN); Yu Wang, Wuhan (CN)

(21) Appl. No.: 19/362,907

(22) Filed: Oct. 20, 2025

(30) Foreign Application Priority Data
Feb. 24, 2025 (CN) 202510206283.3

(51) Int. Cl. G11C 11/406; G11C 11/4072

(52) U.S. Cl. CPC G11C 11/406; G11C 11/4072

(57) ABSTRACT

An example memory device comprises a memory array, the memory array comprises a plurality of memory cells; and a peripheral circuit coupled with the memory array, and the peripheral circuit comprises an initializing circuit, a signal generating circuit and a refreshing circuit; wherein the initializing circuit is configured to perform an initialization process of the memory device after the memory device is powered on; the signal generating circuit is configured to generate the refresh controlling signal and send the refresh controlling signal to the refreshing circuit; and the refreshing circuit is configured to perform at least one pass of refreshing on all the memory cells in the memory array during the initialization process under the control of the refresh controlling signal.

### CROSS-REFERENCE TO RELATED APPLICATIONS

This application claims priority to and the benefit of Chinese Patent Application 202510206283.3, filed on Feb. 24, 2025, which is hereby incorporated by reference in its entirety.

### FIELD OF TECHNOLOGY

Examples of the disclosure relate to the technical field of memory technologies, and in particular, to memory devices, methods of operating memory devices, and memory systems.

### BACKGROUND

With the development of memory technologies, application of memories is becoming more and more widespread. A memory supports read and write operations. Before performing read and write operations on a memory device, it is required to power on the memory firstly, and then read and write operations may be performed on the powered-on memory.

### BRIEF DESCRIPTION OF THE DRAWINGS

In order to more clearly illustrate the technical solutions in the examples of the disclosure, the accompanying drawings that need to be used in the description of examples are briefly described below, and the drawings in the following description are merely some examples of the disclosure, and other drawings may be obtained by those skilled in the art based on these drawings.

FIG. 1 is a schematic structural diagram of an electronic system provided by an example of the disclosure.

FIG. 2 is a schematic structural diagram of another electronic system provided by an example of the disclosure.

FIG. 3 is a schematic structural diagram of an example electronic product of a memory system provided by an example of the disclosure.

FIG. 4 is a schematic structural diagram of a memory device provided by an example of the disclosure.

FIG. 5 is a schematic diagram of the distribution of a memory array and a peripheral circuit in a memory device provided by an example of the disclosure.

FIG. 6 is a schematic top view of the distribution of a memory array and a peripheral circuit in a memory device provided by an example of the disclosure.

FIG. 7 is a schematic structural diagram of a memory cell provided by an example of the disclosure.

FIG. 8 is a schematic structural diagram of another memory device provided by an example of the disclosure.

FIG. 9 is a schematic structural diagram of another memory device provided by an example of the disclosure.

FIG. 10 is a schematic structural diagram of another memory device provided by an example of the disclosure.

FIG. 11 is a schematic structural diagram of another memory device provided by an example of the disclosure.

FIG. 12 is a schematic structural diagram of another memory device provided by an example of the disclosure.

FIG. 13 is a schematic structural diagram of a peripheral circuit provided by an example of the disclosure.

FIG. 14 illustrate individual stages in a process from powering on a memory device to a memory initialization process ending of the powered-on memory device, and a signal timing diagram corresponding to each of stages provided by an example of the disclosure.

FIG. 15 is a flowchart of a method for operating a memory device provided by an example of the disclosure.

FIG. 16 is a schematic structural diagram of a memory system provided by an example of the disclosure.

FIG. 17 is a schematic structural diagram of another memory system provided by an example of the disclosure.

### DETAILED DESCRIPTION

To make the objectives, technical solutions and advantages of the disclosure clearer, the implementations of the disclosure are described in detail below with reference to the accompanying drawings. While example implementations of the disclosure are shown in the drawings, it should be understood that the application may be implemented in various forms and should not be limited by the examples set forth herein. Rather, these implementations are provided to enable a more thorough understanding of the disclosure and to fully convey the scope of the disclosure to those skilled in the art. The drawings all adopt a very simplified form and use a non-precise ratio, which is only used for the purpose of facilitating to illustrate the examples of the disclosure conveniently and clearly.

It should be noted that the terms “first”, “second”, and the like in the disclosure are used to distinguish similar objects, and are not necessarily used to describe a specific order or sequence. It should be understood that such used data may be interchanged wherein appropriate so that examples of the application described herein can be implemented in an order other than those illustrated or described herein. The implementations described in the following examples do not represent all implementations consistent with the disclosure. Rather, they are merely examples consistent with some aspects of the disclosure.

It should be readily understood that the meaning of “on,” “above,” and “over” in the disclosure should be interpreted in the broadest manner, such that “on” not only means “directly on something,” but also comprises the meaning of “on something” and having an intermediate feature or layer therebetween, and “above” or “over” not only means “above” or “over something”, but may also include “over” or “over something” and there is no intermediate feature or layer therebetween (e.g., directly on something).

Further, spatially relative terms such as “below,” “under,” “lower,” “above,” “upper,” and the like are used herein for ease of description to describe a relationship of one element or feature and other element(s) or feature(s) as shown in the figures. The spatially relative terms are intended to encompass different orientations in device use or operation other than the orientation depicted in the figures. The apparatus may be otherwise oriented (rotated 90 degrees or in other orientations), and the spatially relative descriptors used herein may also be interpreted accordingly.

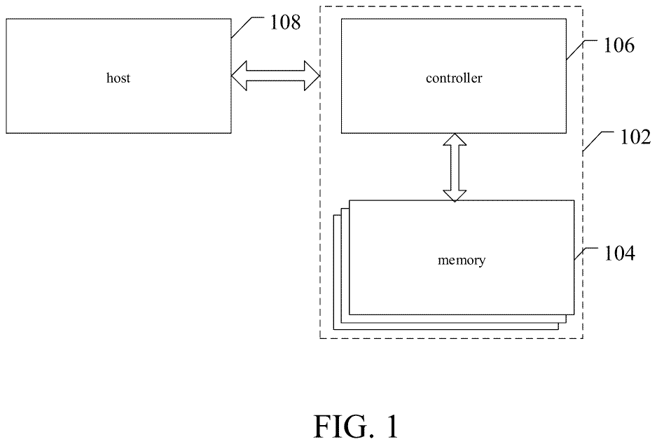

FIG. 1 illustrates a schematic structural diagram of an electronic system provided by an example of the disclosure. In FIG. 1, the electronic system 100 may be a mobile phone, a desktop computer, a laptop computer, a tablet computer, a vehicle computer, a game console, a printer, a pointing device, a wearable electronic device, a smart sensor, a virtual reality (VR) device, an augmented reality (AR) device, or any other suitable electronic device having memories therein. As shown in FIG. 1, the electronic system 100 may include a host 108 and a memory system 102 coupled to the host 108. The host 108 may be a processor (for example, a central processing unit (CPU), a graphics processing unit (GPU)), or a system on chip (SoC) (for example, an application processor (AP)) of the electronic device. The host 108 may be configured to send or receive data to or from the memory device 104 through a controller 106.

The memory system 102 comprises one or more memories 104 and a controller 106; the controller 106 is coupled to the memory device 104 and the host 108 and is configured to control the memory device 104. The controller 106 may manage data stored in the memory device 104 and communicate with the host 108.

The controller 106 may be configured to control operations (such as read, erase, write and refreshing operations) of the memory device 104. In some implementations, the controller 106 is further configured to process an Error Correction Code (ECC) regarding data read from or written to the memory device 104. The controller 106 may also perform any other suitable functions, such as formatting memory device 104. The controller 106 may communicate with an external device (e.g., host 108) according to a particular communication protocol.

In some examples, the controller 106 may communicate with an external device through at least one of various interface protocols, such as a Universal Serial Bus (USB) protocol, a Multi Media Card (MMC) protocol, a Peripheral Component Interconnect (PCI) protocol, a PCI Express (PCI-Express, PCI-E) protocol, an Advanced Technology Attachment (ATA) protocol, a Serial ATA (SATA) protocol, a parallel ATA protocol, a Small Computer System Interface (SCSI) protocol, an Enhanced Small Drive Interface (ESDI) protocol, an Integrated Drive Electronics (IDE) protocol, a Firewire protocol, a Non-Volatile Memory express (NVMe) protocol, or the like.

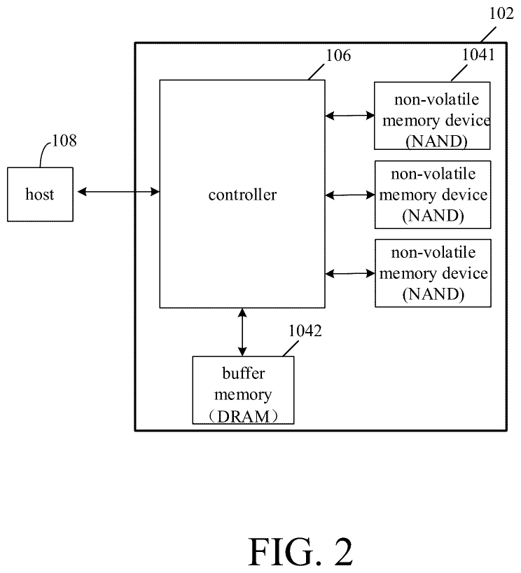

In some examples, the memory device 104 may be any type of memory. In an example, as shown in FIG. 2, the memory device 104 comprises a non-volatile memory device 1041, for example, a NAND (not AND) memory device. The memory device 104 further comprises a buffer memory device 1042, such as a dynamic random-access memory (DRAM). The non-volatile memory device 1041 refers to a storage apparatus capable of retaining data after being powered off, and its main function is long-term storage of data and programs. The buffer memory device 1042 is a high-speed and small-capacity temporary storage area for solving the problem of data transmission matching between two devices with different speeds during data transmission. The data stored in the buffer memory device 1042 is temporary. After the data is processed or transmitted, the contents in the buffer memory device 1042 may be overwritten by new data. Moreover, the data in the buffer memory device 1042 is lost immediately after being powered off because it is mainly used for temporary caching and fast switching of data, and does not bear long-term storage tasks of data.

In some examples, the one or more memories 104 and the controller 106 may be integrated into various types of memory devices, for example, a plurality of memories 104 may be integrated into a memory bank; and the controller 106 may be integrated into a north bridge of a motherboard or directly integrated into a CPU. That is, the memory system 102 may be implemented and packaged into different types of terminal electronics.

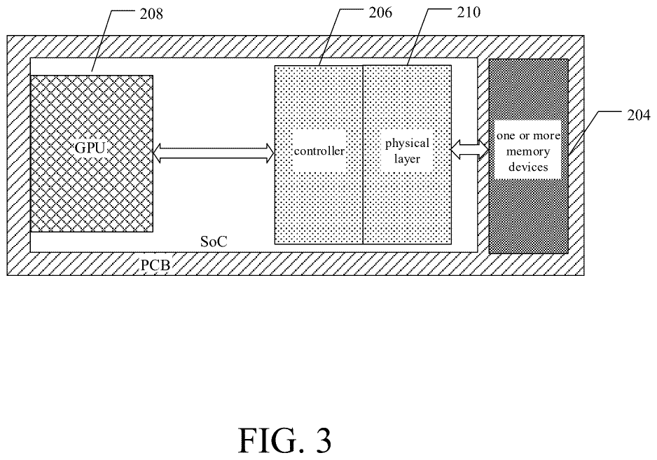

In one example electronic product of the memory system 102 as shown in FIG. 3, the electronic product comprises a SoC and one or more memories 204 fabricated on a printed circuit board (PCB). The PCB is a support for electronic elements in electronic products, and can play a key role in fixing and connecting various electronic elements. The SoC comprises a GPU 208, a controller 206, and a physical layer 210, wherein the controller 206 is responsible for reading and writing instruction scheduling and timing control of the memory device 204; and the physical layer 210 is responsible for completing encoding of the instructions after completion of the scheduling according to a requirement of the memory device 204 and sending corresponding write data to the memory device 204 and receiving data read from the memory device 204.

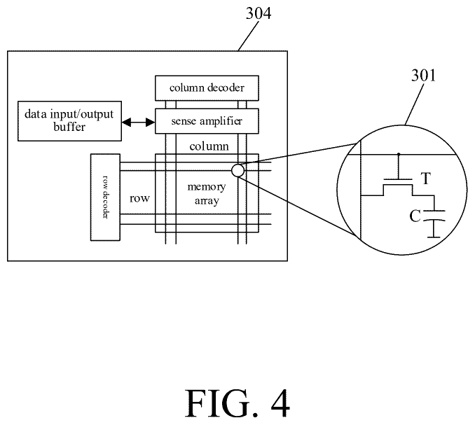

The memory device involved in this disclosure comprises DRAM, FIG. 4 is a schematic structural diagram of a DRAM provided by an example of the disclosure; and the right side in FIG. 4 shows a circuit structure of a memory cell in a DRAM. Each DRAM chip 304 (die) comprises a memory array, the memory array comprises a plurality of memory cells 301 arranged in an array. Each memory cell 301 comprises a transistor T and a capacitor C, and the main operating principle of the memory cell 301 is to use the amount of stored charge in the capacitor to represent whether a binary bit is 1 or 0. The memory cells 301 are arranged in an array and can be regarded as a mesh structure. The memory array specifies addresses using rows and columns. By specifying the intersection of rows and columns (by specifying the row address and column address of the DRAM), the controller may independently access each memory cell 301 in the DRAM chip 304 and perform read, write, or refreshing operations on data stored in the DRAM chip 304.

In some examples, the DRAM may also be directly coupled to the host, for example, the DRAM may be directly coupled to the host as a memory device of the host.

In some examples, a memory device (DRAM) comprises a memory array and a peripheral circuit, wherein the memory array comprises a plurality of memory banks, each memory bank may be divided into a plurality of blocks (or referred as memory bodies), each memory block comprises a plurality of memory cell rows and a plurality of memory cell columns, each memory cell row is coupled to a corresponding one of the word lines, and each memory cell column is coupled to a corresponding one of the bit lines; the peripheral circuit comprises a series of Complementary Metal-Oxide-Semiconductor (CMOS) control circuits; for example, the series of CMOS control circuits comprises: a control circuit corresponding to each memory block, such as a sense amplifier circuit (SA) and a word line driver circuit (WLD), etc.; a control circuit corresponding to each memory bank, for example, a row decoder, and a column decoder, etc.; and a control circuit corresponding to all the memory banks, for example, a command buffer, a command decoder, an address buffer, a data input/output buffer, a mode register, and the like. It should be noted that only the sense amplifier circuit, the row decoder, the column decoder, and the data input/output buffer in the control circuit are shown in FIG. 4, but the examples of the disclosure are not limited thereto.

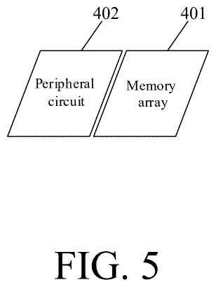

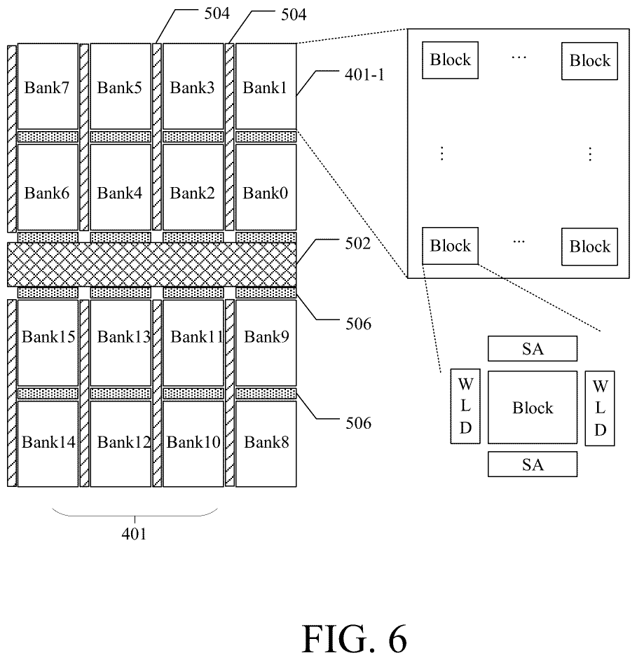

In practical application, the layout between the memory array and the peripheral circuit may be set according to requirements. In some examples, the memory array and the peripheral circuit are arranged in parallel on the same substrate, referring to the schematic diagram of the distribution of the memory array and the peripheral circuit in the example memory shown in FIG. 5 and the schematic top view of the distribution of the memory array and the peripheral circuit in the example memory shown in FIG. 6. In FIG. 5, the memory array 401 and the peripheral circuit 402 are arranged in parallel, and more specifically, the memory array 401 comprises M memory banks, each memory bank comprises N memory blocks, at least one side of each memory block is provided with a control circuit corresponding to the memory block, at least one side of each memory bank is provided with a control circuit corresponding to the memory bank, each K memory banks in the M memory banks form one memory bank row, the M memory banks form M/K memory bank rows, and peripheral circuits corresponding to all the memory banks are arranged between two memory bank rows in the middle. It should be noted that M, N, and K are both positive integers, and M is an integer multiple of K.

For example, as shown in FIG. 6, the memory array 401 comprises 16 memory banks 401-1. Each memory bank comprises a plurality of memory blocks, SA and WLD corresponding to the memory blocks are disposed oppositely around each memory block. A column decoder 504 and a row decoder 506 corresponding to the memory banks are disposed on two sides of each memory bank. One memory bank row is formed for every 4 memory banks, 4 memory bank rows are formed for 16 memory banks, and a control circuit 502 is disposed between two memory bank rows in the middle. It should be noted that the quantity of the memory banks in FIG. 6 is only used In an example, and is not used to limit the quantity of memory banks in the memory in the disclosure.

It should be noted that, the foregoing is merely an example layout of the memory array and the peripheral circuit, and there may be other layouts in practical, and the disclosure does not focus on a layout manner of the memory array and the peripheral circuit, and details are not described herein again. The layout manner of the memory array and the peripheral circuit in the memory device provided in the examples of the disclosure may be various layout manners.

With the development of memory technology, application of memories is becoming more and more widespread. A memory device supports read and write operations. Before performing read and write operations on a memory device, the memory device is required to be powered on firstly, and then read and write operations may be performed on the powered-on memory device.

Powering on the memory device may be prone to put the memory cells in the memory device in an unstable state, and the memory cells in the unstable state may interfere with read and write operations, resulting in lower reliability of read and write operations.

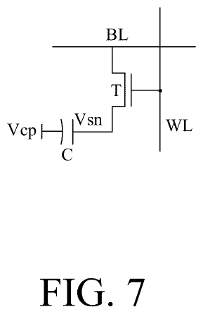

For example, the memory device comprises a DRAM, and the DRAM comprises a memory cell as shown in FIG. 7. The memory cell shown in FIG. 7 comprises a transistor (T) and a capacitor (C). The first electrode of the transistor (T) is electrically connected (or referred as coupled) with a bit line (BL), the second electrode of the transistor (T) is electrically connected (or referred as coupled) with the first electrode plate of the capacitor (C), and the second electrode plate of the capacitor (C) is connected to the reference voltage Vcp. The gate of the transistor (T) is electrically connected (or referred as coupled) with a word line (WL). The word line is to control the transistor (T) to be turned on or off; and the bit line is to perform a read or write operation on the transistor (T) when the transistor (T) is turned on.

Vcp is positively correlated with the supply voltage Vdd of the DRAM, for example, the relationship between Vcp and Vdd is Vcp=½ Vdd. In the process of powering on the DRAM, the reference voltage Vcp may rise to a certain level. Due to the coupling effect, when Vcp rises, Vsn is coupled to an uncertain voltage level by Vcp, so that the memory cell in the memory device is in an unstable state. The memory cell in the unstable state may interfere with the read and write operations, resulting in the reliability of the read and write operations being low.

Vsn refers to a voltage at a storage node (SN), and the SN is connected to a first electrode plate of a capacitor (C) in a memory cell. When a certain amount of charges accumulates on the capacitor (C), a relatively high voltage may be presented at the SN, representing logic “1”; and when the capacitor (C) discharges, the voltage at the SN decreases, representing logic “0”.

When the memory cell undergoes a charge sharing and charge recovery process, the undetermined voltage level at the SN may generate an unbalanced current. Charge sharing refers to a process of a capacitor (C) discharging to a bit line, and charge recovery refers to a process of charging a capacitor (C) by a bit line. The unbalanced current may cause the Vcp to change, for example, cause the Vcp to be higher than the voltage during the normal read and write operations, resulting in an error occurs in read and write data. Therefore, the certainty of Vsn after powering on the DRAM is ensured, so that the memory cell is in a stable state, which is crucial for correct read and write operations of the DRAM.

For example, during normal operation, Vsn is a standard voltage 1.05V representing a logic “1”, when the memory cell undergoes a charge sharing process, Vsn is reduced from 1.05V to 0.6V, and when the memory cell undergoes a charge recovery process, Vsn rises from 0.6V to 1.05V. The current generated when the memory cell undergoes a charge sharing process (the current generated by Vsn reducing from 1.05 to 0.6V), and the current generated when the memory cell undergoes a charge recovery process (the current generated by Vsn rising from 0.6V to 1.05V) are balanced, and this balanced current keeps Vcp unchanged.

However, during a process of powering on the DRAM, Vsn is coupled to an undetermined voltage level, e.g., Vsn is coupled to 0.6V. When the memory cell undergoes a charge sharing process, Vsn decreases from 0.6V to 0.5V. Vsn decreasing during the charge sharing process indicates that a relatively high voltage is presented at the SN. That is, the stored data in the memory cell represents a logic “1”. Therefore, when the memory cell undergoes a charge recovery process, Vsn rises from 0.5V to a standard voltage 1.05V representing a logic “1”. The current generated when the memory cell undergoes the charge sharing process (the current generated by Vsn reducing from 0.6V to 0.5V), and the current generated when the memory cell undergoes a charge recovery process (the current generated by Vsn rising from 0.5V to 1.05V) are unbalanced, and this unbalanced current may increase Vcp. Because Vcp is to provide a stable voltage reference for read and write operations, if Vcp increases, errors in read and write data may be easily caused, thereby reducing reliability of read and write operations.

In an example, the memory device comprises a memory array and a peripheral circuit, the memory array comprises a memory cell, and the peripheral circuit comprises an initializing circuit and a refreshing circuit. The initializing circuit is configured to perform an initialization process of the powered-on memory device, so that the memory reaches a state in which read and write operations are supported. The refreshing circuit is configured to refresh all the memory cells in the memory array after the initialization process ends and before the read and write operations, so as to overcome the problem of unstable memory cells due to powering on.

Based on a solution in an example, after the DRAM is powered on, initialization process is performed on the DRAM first; and after the initialization process ends and before the read and write operations, one pass of refreshing is performed on all memory cells in the DRAM, and Vsn is restored to a normal voltage level through a refreshing operation, thereby ensuring certainty of Vsn and ensuring that the memory cells may be in a stable state. On the basis of this, additional time overheads are required to perform a refreshing operation after the initialization process, and then read and write operations may be performed, and the read and write operations are inefficient.

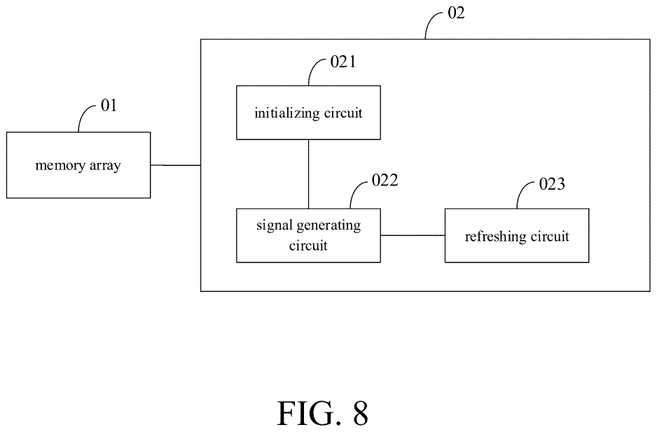

The examples of the disclosure provide a memory device which can improve the reliability of read and write operations and improve the efficiency of the read and write operations. As shown in FIG. 8, the memory device provided in the examples of the disclosure comprises a memory array 01 and a peripheral circuit 02 coupled to the memory array 01. The memory array 01 comprises a plurality of memory cells, and the peripheral circuit 02 comprises an initializing circuit 021, a signal generating circuit 022, and a refreshing circuit 023. The initializing circuit 021 is configured to perform an initialization process of the memory device after the memory device is powered on; the signal generating circuit 022 is configured to generate a refresh controlling signal and send the refresh controlling signal to the refreshing circuit 023; and the refreshing circuit 023 is configured to perform at least one pass of refreshing on all the memory cells in the memory array 01 during the initialization process under the control of the refresh controlling signal. The initializing circuit 021 and the refreshing circuit 023 are connected to the signal generating circuit 022, respectively.

Based on the structure of the memory device described above, at least one pass of refreshing on all the memory cells is performed after the memory device is powered on, and the memory cells may be ensured to be in a stable state through refreshing, so that the adverse impact of the read and write operations due to the unstable state of the memory cells caused by powering on is avoided, and the reliability of the read and write operations is improved.

Compared with the memory device in the foregoing example, the signal generating circuit 022 is newly added in the peripheral circuit 02 in the memory device provided in the examples of the disclosure. The signal generating circuit 022 may generate a refresh controlling signal during the initialization process, and based on this, the refreshing circuit 023 may perform at least one pass of refreshing on all the memory cells during the initialization process under the control of the refresh controlling signal. In other words, in the example of the disclosure, the process of refreshing the memory cells is embedded in the process of initializing the powered-on memory device, and the refreshing of the memory cell is completed before the initialization process ends, so that the read and write operations may be performed immediately after the initialization process ends, without bringing extra time overhead, and the efficiency of the read and write operations is high.

The purpose of performing an initialization process of the memory device is to cause the memory device to reach the state in which read and write operations are supported. That is, an initialization process of the memory device is an operation performed before performing read and write operations on the memory device by the host.

In some examples, the initialization process comprises a configuration information storing stage and a configuration information loading and using stage.

The configuration information storing stage is to store configuration information, wherein the configuration information is to indicate a parameter to be configured for the memory device to cause the memory device to reach a state in which read and write operations are supported, and the configuration information may be determined by a technician. In an example, the configuration information storing stage is to store the configuration information in the storage apparatus, and the type of the storage apparatus is not limited in the examples of the disclosure, for example, the storage apparatus may be a One-Time Program (OTP) apparatus. The OTP apparatus is a device that can only perform one-time programming operation, and contents stored in the OTP apparatus cannot be changed or erased after being programed.

In some examples, during the configuration information storing stage, the initializing circuit 021 first powers on the storage apparatus for storing the configuration information, and then stores the configuration information in the powered-on storage apparatus. In an example, the configuration information storing stage may also be referred as an OTP power-on stage.

In some examples, the configuration information may include, but is not limited to, a trim parameter, a first bit line configuring parameter, a second bit line configuring parameter, a word line configuring parameter, and other parameters.

The trim parameter is to trim various performance parameters in the memory device, for example, to trim parameters such as read and write voltage, read and write time, refreshing cycle, timing and the like.

The first bit line configuring parameter and the second bit line configuring parameter are two different parameters for configuring the bit line. In an example, configuring the bit line may refer to repairing the faulty bit line. In this case, the first bit line configuring parameter and the second bit line configuring parameter are two different information for repairing the faulty bit line. In a long-term use process, a fault may occur on a bit line of a memory device, such as a short circuit or an open circuit, which affects correct reading and writing of data. By repairing the faulty bit line, the faulty bit line may be isolated from the normal work, and a backup bit line may be enabled to work in replace of the faulty bit line, thus the working reliability of the memory device is improved.

In an example, the bit line configuring parameter may include address information for the faulty bit line and address information for the backup bit line. In an example, the address information for the faulty bit line included in the first bit line configuring parameter is different from the address information for the faulty bit line included in the second bit line configuring parameter, that is, the first bit line configuring parameter and the second bit line configuring parameter are to repair different faulty bit lines. In an example, the address information for the backup bit line in the first bit line configuring parameter and the address information for the backup address in the second bit line configuring parameter may be determined by different repair principles. In some examples, the bit line configuring parameter may also be represented as a Column Repair Solution (or COL solution for short).

The word line configuring parameter is a parameter for configuring the word line. For example, configuring the word line may refer to repairing the faulty word line, and in this case, the word line configuration information is information for repairing the faulty word line. The word line is to select memory cells in the memory device, and when a word line fails, the memory cells connected to the word line may not work normally. By repairing the faulty word line, the faulty word line may be isolated from the normal work, and the backup word line is enabled to work in replace of the faulty bit line, so that the word line fault is repaired without affecting other memory cells, to ensure that the memory device may continue to correctly store and read data to improve the working reliability of the memory device. In an example, the word line configuring parameter may include address information for the faulty word line and address information for the backup word line. In some examples, the word line configuring parameter may also be represented as a Row Repair Solution (ROW solution in short).

Other parameters refer to other configuring parameters in the configuration information except the trim parameter, the first bit line configuring parameter, the second bit line configuring parameter, and the word line configuring parameter, for example, a serial identifier (Serial ID) of the memory device, PPR (Post Package Repair) information, TS-to-RM (Temperature Coding for Refreshing Management) information, and the like. The serial number of the memory device is to uniquely identify a certain memory device; the PPR information is to resolve a defect problem that occurs after the memory device is packaged; the TS-to-RM information is to convert the temperature information into a specific code, and the code is to manage a refreshing operation of the memory device, such as a refreshing frequency and a refreshing time.

The configuration information loading and using stage is to load the configuration information and use the loaded configuration information. In some examples, the configuration information loading and using stage comprises a trimming stage, a first bit line configuring stage, a second bit line configuring stage, a word line configuring stage, and other stages.

The trimming stage is for loading the trim parameter from the stored configuration information and trimming the memory device with the trim parameter; the first bit line configuring stage is for loading the first bit line configuring parameter from the stored configuration information and configuring the plurality of bit lines with the first bit line configuring parameter; the second bit line configuring stage is for loading the second bit line configuring parameter from the stored configuration information and configuring the plurality of bit lines with the second bit line configuring parameter; the word line configuring stage is for loading a word line configuring parameter from the stored configuration information and configuring the plurality of word lines with a word line configuring parameter; other stages are for loading other parameters from the stored configuration information and using other parameters.

In an example, the trimming stage may also be referred as a trim loading stage; the first bit line configuring stage may also be referred as a COL solution load (switch) (column address repair address management unit loading (address switch repair)) stage, and the second bit line configuring stage may also be referred as a COL solution load (shift) (row address repair address management unit loading (address shift repair)) stage, and the word line configuring stage may also be referred as a ROW solution load (row address repair address management unit loading) stage.

In some examples, the initializing circuit 021 performs the configuration information storing stage, the trimming stage, the first bit line configuring stage, the second bit line configuring stage, the word line configuring stage, and other stages in sequence during the initialization process of the powered-on memory device.

In some examples, the initializing circuit 021 may also execute a changing state value stage after the execution of other stages is completed. The changing state value stage is to change a state value of the storage apparatus for storing the configuration information, for example, change the state value of the storage apparatus from a default value to a reference value, wherein the default value is to indicate that the configuration information stored in the storage apparatus has not all been loaded, and the reference value is to indicate that the configuration information stored in the storage apparatus has all been loaded. In some examples, the state value of the storage apparatus may be represented as OTP_pd.

In some examples, the initialization process may also be referred as POR (Power On Read).

In some examples, the initializing circuit 021 may include an initialization oscillator and an initialization control circuit, wherein the initialization oscillator is configured to control timing of respective stages in an initialization process, and the initialization control circuit is configured to sequentially perform respective stages according to the timing of respective stages. In some examples, the initialization oscillator may also be referred as a POR oscillator, and the initialization control circuit may also be referred as a POR control circuit.

The signal generating circuit 022 is configured to generate a refresh controlling signal, and send the refresh controlling signal to the refreshing circuit 023. The refresh controlling signal is to control the refreshing circuit 023 to perform at least one pass of refreshing on all memory cells in the memory array 01 during the initialization process. In other words, the signal generating circuit 022 is configured to generate the refresh controlling signal during the initialization process to control the refreshing circuit 023 by the refresh controlling signal to perform at least one pass of refreshing on all the memory cells before the initialization process ends, so as to ensure that the read and write operations may be performed immediately after the initialization process ends, thereby improving the efficiency of the read and write operations. In some examples, the refresh controlling signal may be represented as ref_pulse.

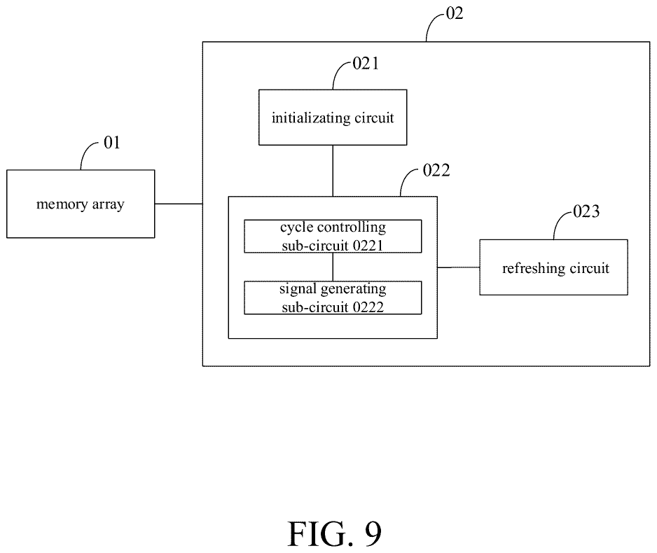

In some examples, the refresh controlling signal comprises a plurality of pulse signals; referring to FIG. 9, the signal generating circuit 022 comprises a cycle controlling sub-circuit 0221 and a signal generating sub-circuit 0222. The cycle controlling sub-circuit 0221 is connected to the signal generating sub-circuit 0222, the cycle controlling sub-circuit 0221 is further connected to the initializing circuit 021, and the signal generating sub-circuit 0222 is further connected to the refreshing circuit 023.

The cycle controlling sub-circuit 0221 is configured to generate a plurality of reference control signals in cycles during the initialization process. The signal generating sub-circuit 0222 is configured to generate one pulse signal based on each reference control signal, and send the one pulse signal to the refreshing circuit 023. For example, every time the cycle controlling signal 0221 generates one reference control signal, the one reference control signal is sent to the signal generating sub-circuit 0222, so that the signal generating sub-circuit 0222 generates one pulse signal based on the one reference control signal.

Generating the plurality of reference control signals in cycles includes generating one reference control signal every other reference cycle. The duration of the reference cycle is not limited in examples of the disclosure, and may be set according to experience, or may be flexibly adjusted according to the number of memory cells to be refreshed, the duration of the initialization process, and the like. In some examples, the duration of the reference cycle is greater than or equal to the duration required for one refreshing operation. The total duration of generating all the reference control signals is less than the duration of the initialization process. In some examples, the reference cycle may be 32 clock cycles.

Each reference control signal is to control the signal generating sub-circuit 0222 to generate one pulse signal, and the one pulse signal is to control the refreshing circuit 023 to perform one refreshing on a portion of the memory cells in the memory array 01 during the initialization process. For example, one pulse signal corresponds to one refreshing operation, the number of memory cells refreshed by one refreshing operation may be set according to experience, or may be flexibly adjusted according to requirements, which is not limited in the examples of the disclosure. For example, the number of memory cells refreshed by one refreshing operation may include the number of memory cells coupled to 16 word lines, or memory cells coupled to 4 word lines, or the like.

The form of the reference control signal is not limited in the examples of the disclosure, as long as it may be ensured that the signal generating sub-circuit 0222 can recognize.

By generating a plurality of reference control signals in cycles and generating one pulse signal based on each reference control signal, the process of the refreshing circuit 023 performing at least one pass of refreshing on all the memory cells may be divided into a plurality of refreshing operations, which is beneficial for improve the normalization of the refreshing process of the refreshing circuit 023 and improving the reliability of the refreshing process.

In some examples, the cycle controlling sub-circuit 0221 may also be referred as a clock divider. For example, the cycle of generating the reference control signal by the cycle controlling sub-circuit 0221 may be 32 clock cycles. In other words, the cycle controlling sub-circuit 0221 and the signal generating sub-circuit 0222 generate one pulse signal (also referred as a REF pulse) every 32 clock cycles. In some examples, if the duration of one clock cycle is 10 ns (nanoseconds), the duration of the 32 clock cycles is 320 ns. In this case, the cycle controlling sub-circuit 0221 may also be referred as 32 DIV (divider). In some examples, the cycle of generating the reference control signal may also be referred as a refreshing cycle. In some examples, the signal generating sub-circuit 0222 may also be referred as an edge detecting circuit, a refreshing pulse generator (REF pulse gen), or the like.

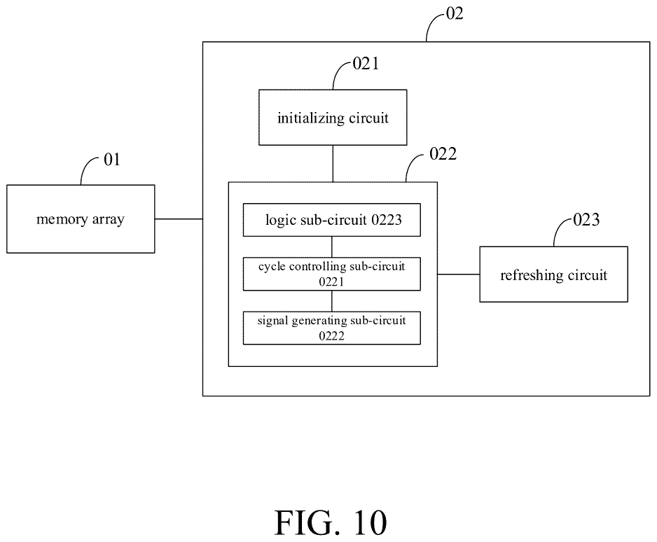

In some examples, referring to FIG. 10, the signal generating circuit 022 further comprises a logic sub-circuit 0223. The logic sub-circuit 0223 is connected to the cycle controlling sub-circuit 0221.

The logic sub-circuit 0223 is configured to generate a first enable signal when a reference condition is satisfied during the initialization process, wherein the satisfied reference condition is to indicate that the pulse signals generated based on the generated reference control signals are not able to perform at least one pass of refreshing on all the memory cells in the memory array 01. The cycle controlling sub-circuit 0221 is configured to generate the plurality of reference control signals in cycles based on the first enable signal. For example, when generating the first enable signal, the logic sub-circuit 0223 sends the first enable signal to the cycle controlling sub-circuit 0221, so that the cycle controlling sub-circuit 0221 may continuously perform the operation of generating the reference control signal in cycles under the first enable signal.

The first enable signal is a signal for enabling the cycle controlling sub-circuit 0221 to continuously generate the reference control signals in cycles. When the reference condition is satisfied, the logic sub-circuit 0223 continuously generates the first enable signals, so that the cycle controlling sub-circuit 0221 continuously generates the reference control signals in cycles, thereby ensuring that at least one pass of refreshing may be successfully performed on all the memory cells during the initialization process, and ensuring the reliability of refreshing. In addition, the first enable signal generated by the logic sub-circuit 0223 is to control the cycle controlling sub-circuit 0221 to generate the reference control signals in cycles, which facilitates improving the controllability of the generation process of the reference control signal.

A form of the first enable signal is not limited in the examples of the disclosure. For example, the first enable signal may be a signal in a high level state or a signal in a low level state.

In some examples, the logic sub-circuit 0223 is further configured to generate a second enable signal when a reference condition is not satisfied. The cycle controlling sub-circuit 0221 is further configured to stop generating the reference control signal based on the second enable signal.

When the reference condition is not satisfied, it indicates that at least one pass of refreshing can be performed on all the memory cells in the memory array 01 with the pulse signals generated based on the generated reference control signals, and at this time, the reference control signal may not be continuously generated. Therefore, the logic sub-circuit 0223 generates a second enable signal, and sends a second enable signal to the cycle controlling sub-circuit 0221, and after receiving the second enable signal, the cycle controlling sub-circuit 0221 stops generating the reference control signal. Based on this, the reference control signal may be stopped to be generated in time in case that at least one pass of refreshing on all the memory cells has been performed, which in turn stops subsequent refreshing operations in time and reduces resource waste.

In an example, after generating the second enable signal, the logic sub-circuit 0223 maintains the second enable signal being unchanged, and continuously outputs the second enable signal. The form of the second enable signal is not limited in the examples of the disclosure, as long as it is ensured that the second enable signal is different from the first enable signal. For example, if the first enable signal is a signal in a high level state, the second enable signal may be a signal in a low level state; and if the first enable signal is a signal in a low level state, the second enable signal may be a signal in a high level state.

In some examples, the logic sub-circuit 0223 may be connected to the initializing circuit 021 and the cycle controlling sub-circuit 0221. The logic sub-circuit 0223 may acquire the progress of the initialization process performed by the initializing circuit 021, may further acquire the number of reference control signals that have been generated by the cycle controlling sub-circuit 0221. The logic sub-circuit 0223 may determine, in real time, whether the reference condition is satisfied during the initialization process according to the acquired information, so as to determine whether to generate the first enable signal or the second enable signal according to the determination result.

In some examples, the logic sub-circuit 0223 may determine, according to a signal input by an input end, whether the reference condition is satisfied, so as to determine whether to generate the first enable signal or the second enable signal according to the determination result. In an example, the logic sub-circuit 0223 has two input ends, a first input end is to input a first signal, and a second input end is to input a second signal. The first signal is to indicate whether the initialization process starts. For example, the first signal may be determined based on an external reset signal. After the memory device is powered on, a reset operation stage is first performed, and initialization process starts only after the reset operation stage ends. The external reset signal is to indicate whether the reset operation stage ends. In an example, the external reset signal and the first signal are a pair of inverted signals. For example, in the reset operation stage, the external reset signal is in a low level state, and the first signal is in a high level state; during the initialization process, the external reset signal is in a high level state, and the first signal is in a low level state.

The second signal is to indicate whether the refreshing process is to be ended. In an example, the second signal is in a low level state by default, and the low level state indicates that the refreshing process is not to be ended; and if the second signal is switched from the low level state to the high level state, it indicates that the refreshing process is to be ended. It should be noted that, after the second signal is switched to the high level state, the second signal may be switched from the high level state to the low level state after a period of time, so as to save resources.

The second signal may be a signal generated inside the peripheral circuit. For example, a statistical circuit exists inside the peripheral circuit, and the statistical circuit may conduct a statistic of the refreshing condition of the memory cells according to the refreshing process of the refreshing circuit 023. When at least one pass of refreshing has not been performed on all the memory cells, the statistical circuit may control the second signal to be in the low level state. When at least one pass of refreshing has been performed on all the memory cells, the statistical circuit may control the second signal to switch from the low level state to the high level state.

For example, the process of determining, by the logic sub-circuit 0223, whether the reference condition is satisfied according to the signal input by the input end comprises: in a case that the first signal indicates that the initialization process starts, if the second signal indicates that the refreshing process is not to be ended, determining that the reference condition is satisfied, and if the second signal indicates that the refreshing process is to be ended, determining that the reference condition is not satisfied.

In some examples, the logic sub-circuit 0223 may also be referred as an RS (reset/set) circuit, a first input end of the logic sub-circuit 023 may be represented as SET, a first signal may be represented as grst, a second input end of the logic sub-circuit 023 may be represented as RST (reset), and a second signal may be represented as por_end_pls. In other words, the grst signal is to enable the cycle controlling sub-circuit 0221, and the por_end_pls signal is to disable the cycle controlling sub-circuit 0221.

In the examples of the disclosure, the refreshing circuit 023 is configured to perform at least one pass of refreshing on all the memory cells in the memory array 01 during the initialization process under the control of the refresh controlling signal.

In the examples of the disclosure, the number of passes of the refreshing on all memory cells is not limited, as long as at least one pass of refreshing on all memory cells being performed is ensured, that is, the number of passes of the refreshing on all memory cells may be any value greater than or equal to 1. For example, the number of passes may be an integer or a decimal. For the case that the number of passes is a decimal, the integer part of the number represents the number of passes that all the memory cells have been refreshed, and the decimal part of the number of passes represents the ratio of the number of the memory cells already refreshed in the latest pass of refreshing to the number of all the memory cells.

In an example, for the case that the refresh controlling signal comprises a plurality of pulse signals, and the signal generating circuit 022 comprises a cycle controlling sub-circuit 0221 and a signal generating sub-circuit 0222, the refreshing circuit 023 is configured to perform one pass of refreshing on a portion of memory cells in the memory array 01 during the initialization process under the control of one pulse signal.

The refreshing by the refreshing circuit 023 under the control of one pulse signal may be referred as one refreshing operation, and the number of the memory cells refreshed by the one refreshing operation in the examples of the disclosure is not limited. For example, all the memory cells may refer to all memory cells in all memory banks in the memory array 01, addresses of word lines coupled to memory cells in different memory banks are the same, and one refreshing operation may refresh memory cells coupled with word lines of certain addresses in all memory banks together. During a pass of refreshing on all memory cells, addresses of word lines corresponding to different refreshing operations are different.

For example, the addresses of the word lines coupled to the memory cells in each memory bank are 0-31, the first refreshing operation may refresh the memory cells in all the memory banks that are coupled to the word lines whose addresses are 0-3 together, the second refreshing operation may refresh the memory cells in all the memory banks that are coupled to the word lines whose addresses are 4-7 together, and so on, and the eighth refreshing operation may refresh the memory cells in all the memory banks that are coupled to the word lines whose addresses are 28-31 together, so as to complete one pass of refreshing on all the memory cells. Then, starting from the ninth refreshing operation, the second refreshing process is entered, and the refreshing sequence of the second refreshing process on the word line is the same as that of the first pass of refreshing process.

In an example, the word lines coupled to all memory cells may include normal word lines and redundant word lines. For example, addresses of word lines corresponding to one memory bank are 0-31, wherein word lines with addresses of 0-24 are normal word lines, and word lines with addresses of 25-31 are redundant word lines. The connection relationship of the normal word lines and connection relationship of the redundant word lines in the memory bank are the same, for example, both the normal word line and the redundant word line are connected with a row of memory cells. A normal word line is a word line that may be sensed by a host when performing read and write operations, and a redundant word line is a word line that may not be sensed by the host when performing read and write operations. The function of the redundant word line is as a backup for the faulty word line when the normal word line fails. After a certain faulty word line is replaced with a backup redundant word line, the memory cells coupled with the faulty word line are replaced with the memory cells coupled with the backup redundant word line.

In some examples, the refreshing circuit 023 is configured to send a refreshing instruction to the word line driver according to a pulse signal in the refresh controlling signal, wherein the address information for the word line coupled to the memory cells to be refreshed is carried in the refreshing instruction, so that the word line driver may determine the word line coupled to the memory cells to be refreshed according to the address information, and apply a turn-on voltage to the determined word line to refresh the memory cells coupled to the determined word line. In some examples, the refreshing instruction may be represented as ref_ab.

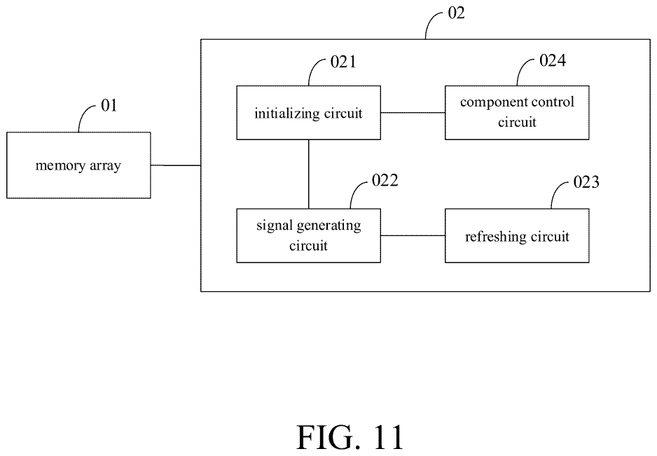

In some examples, referring to FIG. 11, the peripheral circuit 02 further comprises a component control circuit 024. The component control circuit 024 is configured to adjust a state of a reference component from a default state to a state in which a refreshing operation is supported, wherein the reference component is a component to be utilized for refreshing a memory cell.

The reference component is a component to be utilized for refreshing a memory cell. For example, the reference component may include, but are not limited to, a word line driver, a row decoder, a column decoder, a sense amplification circuit, and the like. A default state refers to a state in which a reference component is not working, and a state in which the refreshing operation is supported refers to a state in which a memory cell is being refreshed.

In an example, the component control circuit 024 is connected to the initializing circuit 021, and the component control circuit 024 is configured to, in response to the initialization process starting, adjust the state of the reference component from the default state to the state in which the refreshing operation is supported, so as to prepare performing the refreshing operation by the refreshing circuit 023.

In some examples, the component control circuit 024 is further configured to restore the state of the reference component from the state in which the refreshing operation is supported to the default state.

In an example, the component control circuit 024 is connected to the initializing circuit 021, and the component control circuit 024 is configured to, in response to the initialization process ending, restore the state of the reference component from the state in which the refreshing operation is supported to the default state, so as to restore the reference component to the default state for the use of the subsequent read and write operations and the like.

In some examples, the component control circuit 024 may determine whether the initialization process starts according to the indication signal transmitted by the initializing circuit 021, and determine whether the initialization process ends. In an example, the indication signal is in a low level state in the reset operation stage, switched from the low level state to a high level state at the end of the reset operation stage and the start of the initialization process, and maintained in the high level state all the time during the initialization process; and switched from the high level state to the low level state at the end of the initialization process. The component control circuit 024 may determine that the initialization process starts when it is detected that the indication signal is switched from the low level state to the high level state, and determine that the initialization process ends when it is detected that the indication signal is switched from the high level state to the low level state. In some examples, the indication signal may be represented as por_done.

In some examples, the default state includes a state in which power is turned off and reset control is enabled, the state in which the refreshing operation is supported includes a state in which power is turned on and reset control is disabled, and the reset control is to maintain the reference component in the reset state. That is, in the default state, the reference component is not powered on and remains in the reset state all the time; in the state in which the refreshing operation is supported, the reference component is powered on and the reset state is not maintained.

In an example, restoring the state of the reference component from the state in which the refreshing operation is supported to the default state is implemented by performing a first operation and a second operation, wherein the first operation includes an operation enabling the reset control of the reference component; the second operation includes an operation disconnecting the power supply to the reference component; wherein a complete time of the first operation is earlier than a start time of the second operation.

After the operation enabling the reset control of the reference component is completed, the operation disconnecting the power supply to the reference component is executed, thereby ensuring that the reset control of the reference component has been successfully enabled before the power supply to the reference component is disconnected. It may avoid that the reset control of the reference component cannot be successfully enabled due to the power failure, and the success rate of enabling the reset control is guaranteed.

In an example, adjusting the state of the reference component from the default state to the state in which the refreshing operation is supported is implemented by performing the third operation and the fourth operation, the third operation is an operation for supplying power to the reference component, and the fourth operation is an operation for disabling reset control on the reference component. For example, the complete time of the third operation is earlier than the start time of the fourth operation, thereby ensuring that the reference component is powered on before the reset control is disabled, and ensuring the success rate of canceling the reset control. In some examples, the complete time of the third operation may also be the same as the start time of the fourth operation.

In some examples, supplying power to the reference component may also be referred as turning on a local power source (src_vp). The disabling of the reset control of the reference component may also be referred as releasing the internal reset signal (pd_grst).

In some examples, the memory device further comprises a plurality of word lines coupled to the plurality of memory cells; in a process of refreshing any memory cell, a turn-on voltage is applied on a word line coupled to any memory cell; the initialization process comprises a configuration information storing stage and a word line configuring stage, the word line configuring stage is to load a word line configuring parameter from the stored configuration information and configure the plurality of word lines with word line configuring parameters. In this case, the refreshing circuit 023 is configured to perform at least one pass of refreshing on all the memory cells in the memory array 01 before the word line configuring stage starts under the control of the refresh controlling signal. For descriptions of the configuration information storing stage and the word line configuring stage, reference may be made to the foregoing related description, and details are not described herein again.

In the process of refreshing the memory cell, a turn-on voltage is applied to the word line, and the word line configuring stage is to configure the word line, so that at least one pass of refreshing on all the memory cells may be completed before the word line configuring stage starts, avoiding a conflict generated between the operation of applying the turn-on voltage and the operation of the configuration. In addition, in the word line configuring stage, some faulty word lines are replaced by the backup word lines, and the replaced faulty word lines may not be identified, therefore, at least one pass of refreshing on all the memory cells is completed before the word line configuring stage starts, and it may be ensured that all the memory cells are refreshed for at least one pass, thereby avoiding that those memory cells are still in an unstable state due to the memory cells coupled with the faulty word lines cannot be refreshed, thereby improving the reliability of the read and write operations.

In some examples, the signal generating circuit 022 is configured to generate a refresh controlling signal before the word line configuring stage, so that the refreshing circuit 023 can complete at least one pass of refreshing on all the memory cells before the word line configuring stage starts.

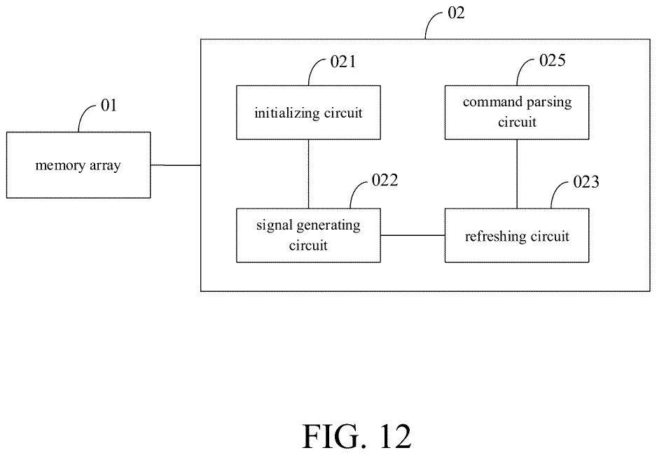

In some examples, referring to FIG. 12, the peripheral circuit 02 further comprises a command parsing circuit 025; and the command parsing circuit 025 is connected to the refreshing circuit 023.

The command parsing circuit 025 is configured to parse a refresh command, obtain a control signal corresponding to the refresh command, wherein the refresh command includes a command generated after the initialization process ends and indicating to refresh target memory cells in the memory array 01. The refreshing circuit 023 is further configured to refresh the target memory cells after the initialization process ends under the control of the control signal corresponding to the refresh command. In some examples, the refresh command may be a command generated by the host. After generating the refresh command, the host may send the refresh command to the controller. After receiving the refresh command, the controller sends the refresh command to the command parsing circuit 025 in the peripheral circuit 02, so that the command parsing circuit 025 receives the refresh command, and parses the refresh command.

That is, the refreshing circuit 023 in the peripheral circuit 02 of the memory device provided in the examples of the disclosure not only supports at least one pass of refreshing on all the memory cells according to the refresh controlling signal during the initialization process, but also supports the refreshing on the target memory cells according to the control signal corresponding to the refresh command after the initialization process ends. The target memory cells may be all memory cells in the memory array 01, or may be a portion of memory cells in the memory array 01, which is not limited in the examples of the disclosure. In some examples, the refresh command may carry address information for the word line. The address information for the word line may be determined by parsing the refresh command, and then the memory cells coupled with the word line corresponding to the address information may be served as the target memory cells.

In some examples, the command parsing circuit 025 may also be referred as a REF DEC (refreshing decoding) circuit, and the control signal corresponding to the refresh command may be represented as cmd_ref_pulse.

In some examples, the peripheral circuit 02 further comprises one OR gate circuit, and the OR gate circuit has two input ends and one output end. The first input end of the OR gate circuit is configured to input the refresh controlling signal, and the second input end of the OR gate circuit is configured to input the control signal corresponding to the refresh command. The output end of the OR gate circuit is connected to the refreshing circuit 023. Since the control signal corresponding to the refresh controlling signal and the control signal corresponding to the refresh command are signals acquired at different periods, the refresh controlling signal and the refresh command are not input into the OR gate circuit at the same time. Therefore, the signal output by the output end of the OR gate circuit is the signal input by the first input end or the second input end.

In some examples, the memory in the examples of the disclosure comprises a DRAM.

Examples of the disclosure provide a strategy for refreshing memory cells of DRAM during POR, and provide a circuit for automatically refreshing the memory cells coupled with all word lines during POR process. In the POR process, the signal generating circuit 022 automatically generates pulse signals for refreshing all memory banks to refresh the memory cells coupled with all word lines, so that Vsn is at the determined voltage level, and the memory cells are in a stable state, thus the problem of data read and write errors caused by uncertain Vsn voltage level is solved.

The memory device, the control circuit (the initializing circuit 021) related to initialization and the control circuit (the refreshing circuit 023) related to the refreshing provided in the examples of the disclosure are reused, and only a few additional circuits (for example, the cycle controlling sub-circuit 0221 and the signal generating sub-circuit 0222) are added to refresh the memory cells. This implementation is simple, and the problem of data read and write errors caused by uncertain Vsn voltage level may be solved by using fewer resources. In addition, the process of refreshing the memory cells is embedded in the POR process without affecting subsequent normal read and write operations.

According to the solution provided by the examples of the disclosure, at least one pass of refreshing is performed on all the memory cells after the memory device is powered-on, and it may be ensured that the memory cells may be in a stable state by refreshing, so that the adverse impact of the unstable state of the memory cells caused by the power-on on the read and write operations is avoided, and the reliability of the read and write operations is improved. In addition, the process of refreshing the memory cells is embedded in the process of initializing the powered-on memory device, and the refreshing of the memory cell is completed before the initialization process ends, so that the read and write operations may be performed immediately after the initialization process ends, without bringing extra time overhead, and the efficiency of the read and write operations is high.

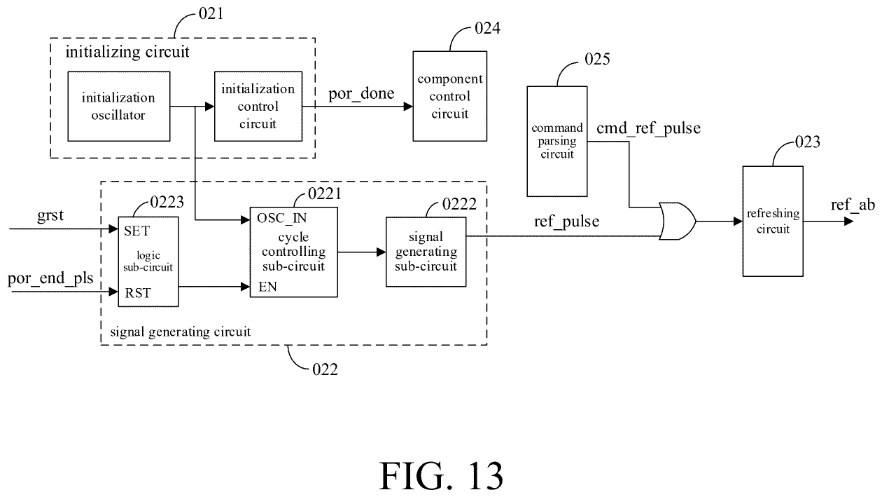

In an example, the structure of the peripheral circuit 02 is shown in FIG. 13. The peripheral circuit 02 comprises an initializing circuit 021, a signal generating circuit 022, a refreshing circuit 023, a component control circuit 024, and a command parsing circuit 025.

The initializing circuit 021 comprises an initialization oscillator and an initialization control circuit connected to each other. The initialization oscillator is configured to control the timing of respective stages in the initialization process, and the initialization control circuit is configured to sequentially perform respective stages according to the timing of respective stages.

The signal generating circuit 022 comprises a cycle controlling sub-circuit 0221, a signal generating sub-circuit 0222, and a logic sub-circuit 0223. The logic sub-circuit 0223 is connected to the cycle controlling sub-circuit 0221, and the cycle controlling sub-circuit 0221 is connected to the signal generating sub-circuit 0222. The logic sub-circuit 0223 is configured to, during the initialization process, generate a first enable signal when the reference condition is satisfied; and generate a second enable signal when the reference condition is not satisfied; and the satisfied reference condition is to indicate that the pulse signals generated based on the generated reference control signals are not able to perform at least one pass of refreshing on all the memory cells. The cycle controlling sub-circuit 0221 is configured to generate a plurality of reference control signals in cycles based on the first enable signal; and stop generating the reference control signal based on the second enable signal. The signal generating sub-circuit 0222 is configured to generate a plurality of pulse signals based on the plurality of reference control signals.

The plurality of pulse signals may constitute a refresh controlling signal (ref_pulse), and the signal generating circuit 022 is connected to the refreshing circuit 023 through an OR gate circuit. That is, the signal generating circuit 022 enables the refreshing circuit 023 to receive the refresh controlling signal by inputting the refresh controlling signal into the OR gate circuit.

In some examples, the initialization oscillator in the initializing circuit 021 is connected to the cycle controlling sub-circuit 0221, and the initialization oscillator may synchronize the clock cycle to the cycle controlling sub-circuit 0221, so that the cycle controlling sub-circuit 0221 generates the cycle of the reference control signal according to the clock cycle. In some examples, the cycle controlling sub-circuit 0221 has two input ends, represented as OSC_IN (oscillator input) and EN (enable), respectively. Connecting the initialization oscillator and the cycle controlling sub-circuit 0221 indicates that the initialization oscillator is connected to the input end OSC_IN of the cycle controlling sub-circuit 0221; and connecting the logic sub-circuit 0223 and the cycle controlling sub-circuit 0221 indicates that the logic sub-circuit 0223 is connected to the input end EN of the cycle controlling sub-circuit 0221.

In some examples, the logic sub-circuit 0223 determines whether the reference condition is satisfied according to the signal input by the input end. The logic sub-circuit 0223 has two input ends, represented as SET and RST, respectively. The input end SET of the logic sub-circuit 0223 is to input a first signal (grst), and the input end RST of the logic sub-circuit 0223 is to input a second signal (por_end_pls). In a case that the first signal indicates that the initialization process starts, if the second signal indicates that the refreshing process is not to be ended, it is determined that the reference condition is satisfied, and if the second signal indicates that the refreshing process is to be ended, it is determined that the reference condition is not satisfied.

The component control circuit 024 is connected to the initialization control circuit in the initializing circuit 021, the initialization control circuit may transmit an indication signal (por_done) to the component control circuit 024, and the component control circuit 024 may determine, according to the indication signal, whether the initialization process starts, and determine whether the initialization process ends; in response to the initialization process starting, the state of the reference component is adjusted from the default state to the state in which the refreshing operation is supported; and in response to the initialization process ending, the state of the reference component is restored from the state in which the refreshing operation is supported to the default state.

The command parsing circuit 025 is configured to parse a refresh command, obtain a control signal corresponding to the refresh command (cmd_ref_pulse), wherein the refresh command includes a command generated after the initialization process ends and indicating to refresh a target memory cell. The command parsing circuit 025 is connected to the refreshing circuit 023 through an OR gate circuit. That is, the command parsing circuit 025 enables the refreshing circuit 023 to receive the control signal corresponding to the refresh command by inputting the control signal corresponding to the refresh command into the OR gate circuit.

The refreshing circuit 023 is configured to perform at least one pass of refreshing on all the memory cells during the initialization process under the control of the refresh controlling signal; and refresh the target memory cell after the initialization process ends under the control of the control signal corresponding to the refresh command. In some examples, the refreshing circuit 023 is configured to send a refresh command (ref_ab) to the word line driver according to the pulse signal in the refresh controlling signal or according to the control signal corresponding to the refresh command. The refresh command carries address information for the word line coupled to the memory cells to be refreshed at present, so that the word line driver may determine the word line coupled to the memory cells to be refreshed at present according to the address information, and apply a turn-on voltage to the determined word line to refresh the memory cells coupled to the determined word line.

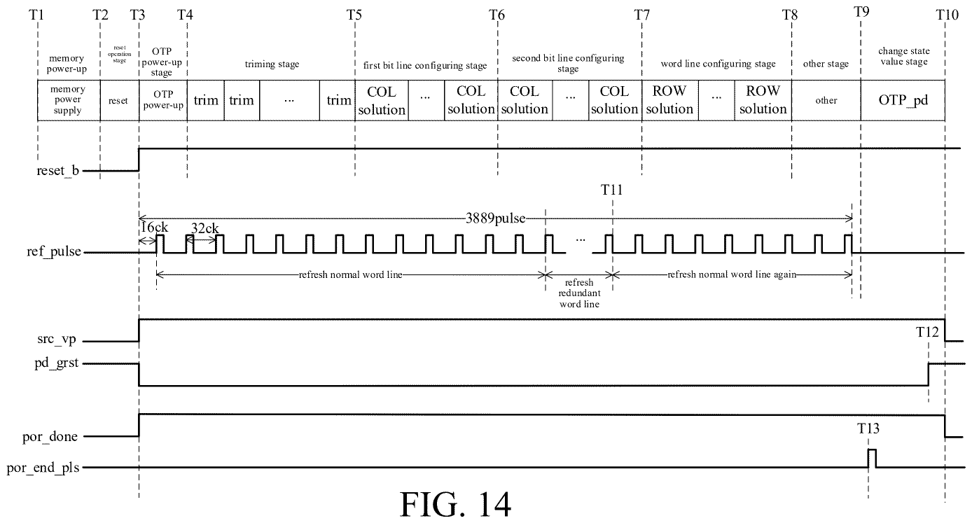

In an example, respective stages in a process of powering on a memory device to an end of a memory initialization process of the powered-on memory device, and a signal timing diagram corresponding to respective stages provided by an example of the disclosure are shown in FIG. 14.

The process from powering-up the memory device to the end of memory initialization of the powered-on memory includes the following stages: a memory power-on stage, a reset operation stage, an OTP power-on stage, a trimming stage, a first bit line configuring stage, a second bit line configuring stage, a word line configuring stage, other stage and a changing state value stage, and the timing of respective stages is shown in FIG. 14. The memory power-on stage lasts from the moment T1 to the moment T2, the reset operation stage lasts from the moment T2 to the moment T3, the OTP power-on stage lasts from the moment T3 to the moment T4, the trimming stage lasts from the moment T4 to the moment T5, the first bit line configuring stage lasts from the moment T5 to the moment T6, the second bit line configuring stage lasts from the moment T6 to the moment T7, the word line configuring stage lasts from the moment T7 to the moment T8, the other stage lasts from the moment T8 to the moment T9, and the changing state value stage lasts from the moment T9 to the moment T10. The OTP power-on stage, the trimming stage, the first bit line configuring stage, the second bit line configuring stage, the word line configuring stage, the other stage, and the changing state value stage belong to the initialization process, that is, the initialization process lasts from T3 to T10.

Label reset_b represents the external reset signal. Before the start of the initialization process (before the moment T3), the reset_b is in a low level state. Before the start of the initialization process (before T3 moment), reset_b is switched from the low level state to the high level state. After the start of the initialization process (after the T3 moment), reset_b remains in a high level state. The switching of the reset_b from the low level state to the high level state indicates that the initialization process starts.

Label ref_pulse represents the refresh controlling signal, ref_pulse comprises 3889 pulse signals for performing at least one pass of refreshing on all memory cells. The time interval between two adjacent pulse signals is 32 cks (clock cycle). A time interval of 16 cks may exist between the time instance for generating the first pulse signal and the time instance (the moment T3) for starting the initialization process, and the time interval of 16 cks is to reserve a certain period for the component control circuit 024 adjusting the state of the reference component from the default state to the state in which the refreshing operation is supported.

It can be seen from FIG. 14 that, in the process of performing at least one pass of refreshing on all the memory cells with the 3889 pulse signals, the memory cells coupled to the normal word lines are all refreshed in one pass with a portion of the pulse signals, and then the memory cells coupled to the redundant word lines are all refreshed with a portion of the pulse signals. At this point, the refreshing of all memory cells is complete. Then, the memory cells coupled to the normal word lines are refreshed with the remain pulse signals again. The end time (the moment T11) of the last pulse signal which is utilized to complete one pass of refreshing on all the memory cells is earlier than the start time (the moment T7) of the word line configuring stage, so as to ensure that one pass of refreshing of all the memory cells is completed before the start of the word line configuring stage. The end time of the last pulse signal of the 3889 pulse signals is earlier than the end time of the initialization process (the moment T10).

Label src_vp represents an internal power supply signal. Before the start of the initialization process (before the moment T3), src_vp is in a low level state; at the start time (the moment T3) of the initialization process, src_vp is switched from the low level state to the high level state; during the initialization process (the time period between the moment T3 and the moment T10), src_vp is in the high level state; at the end time (the moment T10) of the initialization process, src_vp is switched from the high level state to the low level state. The switching of src_vp from the low level state to the high level state indicates that the local power supply is to be turned on to supply power to the reference component. The switching of the src_vp from the high level state to the low level state indicates that the local power supply is to be turned off, thereby disconnecting the power supply to the reference component.

Label pd_grst represents an internal reset signal. Before the start of the initialization process (before the moment T3), pd_grst is in a high level state; at the start time (the moment T3) of the initialization process, pd_grst is switched from the high level state to the low level state; during the time period from the moment T3 to the moment T12, pd_grst is in the low level state; at the moment T12, pd_grst is switched from the low level state to the high level state. The switch of pd_grst from a high-level state to a low-level state indicates that the reset control of the reference component has been disabled; The switch of pd_grst from a low level state to a high level state indicates that the reset control of the reference component has been enabled. It can be seen from FIG. 14 that the moment T12 is earlier than the moment T10. That is, it indicates that the complete time of the operation enabling the reset control of the reference component is earlier than the start time for disconnecting the power supply to the reference component.

Label por_done represents an indication signal. Before the start of the initialization process (before the moment T3), por_done is in a low level state; at the start time (the moment T3) of the initialization process, por_done is switched from the low level state to the high level state; during the initialization process (the time period between the moment T3 and the moment T10), por_done is in the high level state; at the end time (the moment T10) of the initialization process, por_done is switched from the high level state to the low level state. The switching of the por_done from the low level state to the high level state indicates that the initialization process starts, and the switching of the por_done from the high level state to the low level state indicates that the initialization process ends.

Label por_end_pls represents a second signal. Before the moment T13, por_end_pls is in a low level state. At the moment T13, por_end_pls is switched from the low level state to the high level state. The switching of por_end_pls from the low level state to the high level state indicates that the refreshing process is to be ended. After a period of time after the moment T13, por_end_pls is switched from the high level state to the low level state to save resources. It can be learned from FIG. 14 that the moment T13 is earlier than the moment T10. That is, it indicates that the end time of the refreshing process is earlier than the end time of the initialization process, so as to ensure that the read and write operations may be performed immediately after the initialization process is ended, thereby improving the efficiency of the read and write operations. In addition, the end time of the last pulse signal in the 3889 pulse signals in ref_pulse is earlier than the moment T13, that is, it indicates that generation of the pulse signals is stopped when the refreshing process is to be ended.

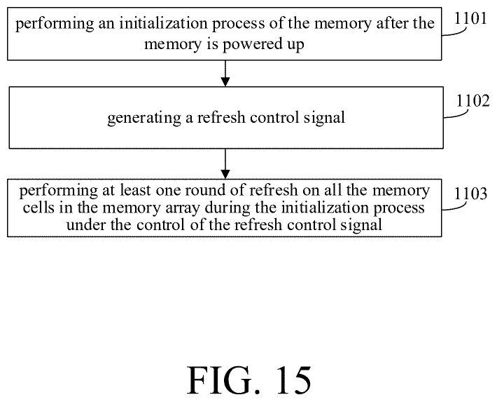

An example of the disclosure provides a method for operating a memory device, wherein the memory device comprises a memory array, and the memory array comprises a plurality of memory cells. In an example, the memory device further comprises a peripheral circuit coupled to the memory array, and the method for operating the memory may be performed by the peripheral circuit. The memory device may be the memory device in FIG. 8 to FIG. 12. Referring to FIG. 15, the method for operating the memory device comprises the following operations 1101 to 1103:
Operation 1101: performing an initialization process of the memory device after the memory device is powered on.
Operation 1102: generating a refresh controlling signal.

In some examples, the refresh controlling signal comprises a plurality of pulse signals; and generating the refresh controlling signal comprises:
generating a plurality of reference control signals in cycles during the initialization process;
generating one pulse signal based on each reference control signal; and
performing one pass of refreshing on a portion of the memory cells in the memory array during the initialization process under the control of the one pulse signal.

In some examples, generating a plurality of reference control signals in cycles during the initialization process comprises:
generating a first enable signal when a reference condition is satisfied during the initialization process; and the satisfied reference condition is to indicate that the pulse signals generated based on the generated reference control signals are not able to perform at least one pass of refreshing on all the memory cells in the memory array; and
generating the plurality of reference control signals in cycles based on the first enable signal.

In some examples, the method further comprises:
generating a second enable signal when the reference condition is not satisfied; and
stopping generating the reference control signals based on the second enable signal.

Operation 1103: performing at least one pass of refreshing on all the memory cells in the memory array during the initialization process under the control of the refresh controlling signal.

In some examples, the method further comprises:
adjusting a state of a reference component from a default state to a state in which a refreshing operation is supported, wherein the reference component is a component to be utilized for refreshing a memory cell.

In some examples, the method further comprises:
restoring the state of the reference component from the state in which the refreshing operation is supported to the default state.

In some examples, the default state includes a state in which power is turned off and reset control is enabled, the state in which the refreshing operation is supported includes a state in which power is turned on and reset control is disabled, and the reset control is to maintain the reference component in the reset state;
restoring the state of the reference component from the state in which the refreshing operation is supported to the default state is implemented by performing a first operation and a second operation, wherein the first operation includes an operation enabling the reset control of the reference component; the second operation includes an operation disconnecting the power supply to the reference component; wherein a complete time of the first operation is earlier than a start time of the second operation.

In some examples, the memory device further comprises a plurality of word lines coupled to the plurality of memory cells; in a process of refreshing any one of the memory cells, a turn-on voltage is applied on a word line coupled to the one memory cell;
the initialization process comprises a configuration information storing stage and a word line configuring stage, wherein the word line configuring stage is to load a word line configuring parameter from stored configuration information and configure the plurality of word lines with the word line configuring parameter; and
performing at least one pass of refreshing on all the memory cells in the memory array during the initialization process under the control of the refresh controlling signal comprises:
performing at least one pass of refreshing on all the memory cells in the memory array before the word line configuring stage starts under the control of the refresh controlling signal.

In some examples, the method further comprises:
parsing a refresh command, obtain a control signal corresponding to the refresh command, wherein the refresh command includes a command generated after the initialization process ends and indicating to refresh a target memory cell in the memory array; and
refreshing the target memory cell after the initialization process ends under the control of the control signal corresponding to the refresh command.

The description of the above example of the method for operating a memory device has the beneficial effects similar to the hardware example of the above memory device (the examples shown in FIGS. 8 to 12). For the technical details not disclosed in the example of the method for operating a memory device, please refer to the description of the hardware example of the memory device of the disclosure, which is not repeated here.

Based on the same concept, an example of the disclosure further provides
a memory device, and the memory device comprises:
a memory array comprising a plurality of memory cells; and a peripheral circuit coupled with the memory array, the peripheral circuit comprises a signal generating circuit, and an initializing circuit and a refreshing circuit which are connected to the signal generating circuit;
wherein the signal generating circuit comprises a cycle controlling sub-circuit and a signal generating sub-circuit connected to each other;
the cycle controlling sub-circuit is configured to generate a plurality of reference control signals in cycles during the initialization process of the powered-on memory device by the initializing circuit; and
the signal generating sub-circuit is configured to generate a plurality of pulse signals based on the plurality of reference control signals, wherein the plurality of pulse signals are to control the refreshing circuit to perform at least one pass of refreshing on all the memory cells in the memory array during the initialization process.

In an example, the signal generating circuit may include the signal generating circuit 022 in FIG. 8 to FIG. 12. The initializing circuit may include the initializing circuit 021 in FIG. 8 to FIG. 12. The refreshing circuit may include the refreshing circuit 023 in FIG. 8 to FIG. 12. The cycle controlling sub-circuit may include the cycle controlling sub-circuit 0221 in FIG. 9 and FIG. 10. The signal generating sub-circuit may include the signal generating sub-circuit 0222 in FIG. 9 and FIG. 10.

In some examples, the signal generating circuit further comprises a logic sub-circuit connected to the cycle controlling sub-circuit;
the logic sub-circuit is configured, during the initialization process, to generate a first enable signal when a reference condition is satisfied and to generate a second enable signal when a reference condition is not satisfied, wherein the satisfied reference condition is to indicate that the pulse signals generated based on the generated reference control signals are not able to perform at least one pass of refreshing on all the memory cells in the memory array; and
the cycle controlling sub-circuit is configured to generate the plurality of reference control signals in cycles based on the first enable signal; and stop generating the reference control signals based on the second enable signal.

For example, the logic sub-circuit may be the logic sub-circuit 0223 in FIG. 10.

In some examples, the peripheral circuit further comprises a component control circuit. The component control circuit is configured to adjust a state of a reference component from a default state to a state in which a refreshing operation is supported, wherein the reference component is a component to be utilized for refreshing a memory cell. In some examples, the component control circuit is further configured to restore the state of the reference component from the state in which the refreshing operation is supported to the default state.

In some examples, the default state includes a state in which power is turned off and reset control is enabled, the state in which the refreshing operation is supported includes a state in which power is turned on and reset control is disabled, and the reset control is to maintain the reference component in a reset state; restoring the state of the reference component from the state in which the refreshing operation is supported to the default state is implemented by performing a first operation and a second operation, wherein the first operation includes an operation enabling the reset control of the reference component; the second operation includes an operation disconnecting the power supply to the reference component; wherein a complete time of the first operation is earlier than a start time of the second operation.

In an example, the component control circuit may be the component control circuit 024 in FIG. 11.

In some examples, the memory device further comprises a plurality of word lines coupled to the plurality of memory cells; in a process of refreshing any one of the memory cells, a turn-on voltage is applied on a word line coupled to the one memory cell;
the initialization process comprises a configuration information storing stage and a word line configuring stage, wherein the word line configuring stage is to load a word line configuring parameter from stored configuration information and configure the plurality of word lines with the word line configuring parameter; and
the plurality of pulse signals are to control the refreshing circuit to perform at least one pass of refreshing on all the memory cells in the memory array before the word line configuring stage starts.

In some examples, the peripheral circuit further comprises a command parsing circuit connected to the refreshing circuit;
the command parsing circuit is configured to parse a refresh command, obtain a control signal corresponding to the refresh command, wherein the refresh command includes a command generated after the initialization process ends and indicating to refresh a target memory cell in the memory array; and the control signal corresponding to the refresh command is to control the refreshing circuit to refresh the target memory cell after the initialization process ends.

In an example, the command parsing circuit may be the command parsing circuit 025 in FIG. 12.

The description of the above hardware example of the memory device has the beneficial effects similar to the hardware example of the foregoing memory device (the example shown in FIG. 8 to FIG. 12). For the technical details not disclosed in the above hardware example of the memory device, please refer to the description of the hardware example of the foregoing memory device of the disclosure, which is not repeated here.

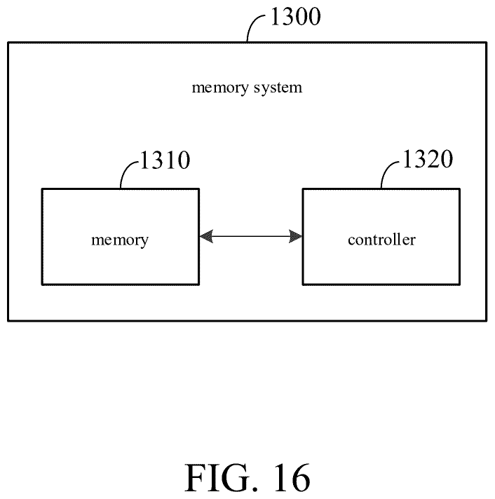

An example of the disclosure provides a memory system, as shown in FIG. 16. The memory system 1300 comprises a memory device 1310 and a controller 1320 coupled to the memory device 1310. The controller 1320 is configured to control the memory device 1310. The memory device 1310 may be any one of the foregoing memory devices.

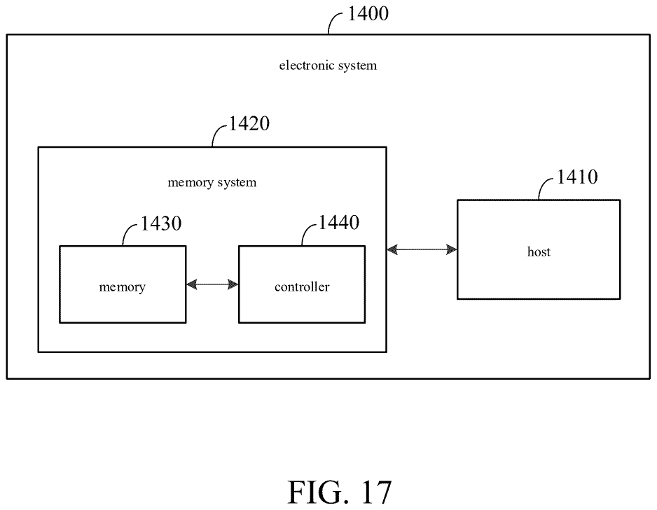

An example of the disclosure provides an electronic system, as shown in FIG. 17. The electronic system 1400 comprises a host 1410 and a memory system 1420 coupled to the host 1410. The memory system 1420 comprises a memory device 1430 and a controller 1440 coupled to the memory device 1430. The controller 1440 is configured to control the memory device 1430. In an example, the memory device 1430 may be any one of the foregoing memory devices.

It should be understood that “multiple” referred to herein means two or more. “And/or” describes an association relationship of associated objects, meaning that three relationships may exist, for example, A and/or B may indicate the following three situations: A alone, both A and B, or B alone. The symbol “/” generally indicates that the front-back associated object is a “or” relationship.

Examples of the disclosure provide a memory device, an operation method of the memory device and a memory system. The technical solution is as follows:

According to an aspect, an example of the disclosure provides a memory device, comprising:
a memory array comprising a plurality of memory cells; and
a peripheral circuit coupled with the memory array, the peripheral circuit comprising an initializing circuit, a signal generating circuit and a refreshing circuit;
wherein the initializing circuit is configured to perform an initialization process of the memory device after the memory device is powered on;
the signal generating circuit is configured to generate the refresh controlling signal and send the refresh controlling signal to the refreshing circuit; and the refreshing circuit is configured to perform at least one pass of refreshing on all the memory cells in the memory array during the initialization process under the control of the refresh controlling signal.

In some examples, the refresh controlling signal comprises a plurality of pulse signals; the signal generating circuit comprises a cycle controlling sub-circuit and a signal generating sub-circuit;
the cycle controlling sub-circuit is configured to generate a plurality of reference control signals in cycles during the initialization process;
the signal generating sub-circuit is configured to generate one pulse signal based on each reference control signal, and send the one pulse signal to the refreshing circuit; and
the refreshing circuit is configured to perform one pass of refreshing on a portion of the memory cells in the memory array during the initialization process under the control of the one pulse signal.

In some examples, the signal generating circuit further comprises a logic sub-circuit;
the logic sub-circuit is configured to generate a first enable signal when a reference condition is satisfied during the initialization process, wherein the satisfied reference condition is to indicate that pulse signals generated based on generated reference control signals are not able to perform at least one pass of refreshing on all the memory cells in the memory array; and
the cycle controlling sub-circuit is configured to generate the plurality of reference control signals in cycles based on the first enable signal.

In some examples, the logic sub-circuit is further configured to generate a second enable signal when a reference condition is not satisfied; and
the cycle controlling sub-circuit is further configured to stop generating the reference control signals based on the second enable signal.

In some examples, the peripheral circuit further comprises a component control circuit;
the component control circuit is configured to adjust a state of a reference component from a default state to a state in which a refreshing operation is supported, wherein the reference component is a component to be utilized for refreshing a memory cell.

In some examples, the component control circuit is further configured to restore the state of the reference component from the state in which the refreshing operation is supported to the default state.

In some examples, the default state includes a state in which power is turned off and reset control is enabled, the state in which the refreshing operation is supported includes a state in which power is turned on and reset control is disabled, and the reset control is to maintain the reference component in a reset state; and
restoring the state of the reference component from the state in which the refreshing operation is supported to the default state is implemented by performing a first operation and a second operation, wherein the first operation includes an operation enabling the reset control of the reference component; the second operation includes an operation disconnecting the power supply to the reference component;
wherein a complete time of the first operation is earlier than a start time of the second operation.

In some examples, the memory device further comprises a plurality of word lines coupled to the plurality of memory cells; in a process of refreshing any one of the memory cells, a turn-on voltage is applied on a word line coupled to the one memory cell;
the initialization process comprises a configuration information storing stage and a word line configuring stage, wherein the word line configuring stage is to load a word line configuring parameter from stored configuration information and configure the plurality of word lines with the word line configuring parameter; and
the refreshing circuit is configured to perform at least one pass of refreshing on all the memory cells in the memory array before the word line configuring stage starts under the control of the refresh controlling signal.

In some examples, the peripheral circuit further comprises a command parsing circuit;
the command parsing circuit is configured to parse a refresh command, obtain a control signal corresponding to the refresh command, wherein the refresh command includes a command generated after the initialization process ends and indicating to refresh a target memory cell in the memory array; and
the refreshing circuit is further configured to refresh the target memory cell after the initialization process ends under the control of the control signal corresponding to the refresh command.

According to another aspect, an example of the disclosure provides a method for operating a memory device, wherein the memory device comprises a memory array, and the memory array comprises a plurality of memory cells; the method comprises:
performing an initialization process on the memory device after the memory device is powered on;
generating a refresh controlling signal;
perform at least one pass of refreshing on all the memory cells in the memory array during the initialization process under the control of the refresh controlling signal.

In some examples, the refresh controlling signal comprises a plurality of pulse signals; generating the refresh controlling signal comprises:
generating a plurality of reference control signals in cycles during the initialization process;
generating one pulse signal based on each reference control signal; and
performing one pass of refreshing on a portion of the memory cells in the memory array during the initialization process under the control of the one pulse signal.

In some examples, generating a plurality of reference control signals in cycles during the initialization process comprises:
generating a first enable signal when a reference condition is satisfied during the initialization process, wherein the satisfied reference condition is to indicate that the pulse signals generated based on the generated reference control signals are not able to perform at least one pass of refreshing on all the memory cells in the memory array; and
generating the plurality of reference control signals in cycles based on the first enable signal.

In some examples, the method further comprises:
generating a second enable signal when the reference condition is not satisfied; and
stopping generating the reference control signals based on the second enable signal.

In some examples, the method further comprises:
adjusting a state of a reference component from a default state to a state in which a refreshing operation is supported, wherein the reference component is a component to be utilized for refreshing a memory cell.

In some examples, the method further comprises:
restoring the state of the reference component from the state in which the refreshing operation is supported to the default state.

In some examples, the default state includes a state in which power is turned off and reset control is enabled, the state in which the refreshing operation is supported includes a state in which power is turned on and reset control is disabled, and the reset control is to maintain the reference component in a reset state; and
restoring the state of the reference component from the state in which the refreshing operation is supported to the default state is implemented by performing a first operation and a second operation, wherein the first operation includes an operation enabling the reset control of the reference component; the second operation includes an operation disconnecting the power supply to the reference component;
wherein a complete time of the first operation is earlier than a start time of the second operation.

In some examples, the memory device further comprises a plurality of word lines coupled to the plurality of memory cells; in a process of refreshing any one of the memory cells, a turn-on voltage is applied on a word line coupled to the one memory cell;
the initialization process comprises a configuration information storing stage and a word line configuring stage, wherein the word line configuring stage is to load a word line configuring parameter from stored configuration information and configure the plurality of word lines with the word line configuring parameter; and
performing at least one pass of refreshing on all the memory cells in the memory array during the initialization process under the control of the refresh controlling signal comprises:
performing at least one pass of refreshing on all the memory cells in the memory array before the word line configuring stage starts under the control of the refresh controlling signal.

In some examples, the method further comprises:
parsing a refresh command, obtain a control signal corresponding to the refresh command, wherein the refresh command includes a command generated after the initialization process ends and indicating to refresh a target memory cell in the memory array; and
refreshing the target memory cell after the initialization process ends under the control of the control signal corresponding to the refresh command.

According to another aspect, an example of the disclosure provides a memory device, comprising:
a memory array comprising a plurality of memory cells; and
a peripheral circuit coupled with the memory array, the peripheral circuit comprises a signal generating circuit, and an initializing circuit and a refreshing circuit which are connected to the signal generating circuit;
wherein the signal generating circuit comprises a cycle controlling sub-circuit and a signal generating sub-circuit connected to each other;
the cycle controlling sub-circuit is configured to generate a plurality of reference control signals in cycles during the initialization process of the powered-on memory device by the initializing circuit; and
the signal generating sub-circuit is configured to generate a plurality of pulse signals based on the plurality of reference control signals, wherein the plurality of pulse signals are to control the refreshing circuit to perform at least one pass of refreshing on all the memory cells in the memory array during the initialization process.

In some examples, the signal generating circuit further comprises a logic sub-circuit connected to the cycle controlling sub-circuit;
the logic sub-circuit is configured, during the initialization process, to generate a first enable signal when a reference condition is satisfied and to generate a second enable signal when a reference condition is not satisfied, wherein the satisfied reference condition is to indicate that the pulse signals generated based on the generated reference control signals are not able to perform at least one pass of refreshing on all the memory cells in the memory array; and
the cycle controlling sub-circuit is configured to generate the plurality of reference control signals in cycles based on the first enable signal; and stop generating the reference control signals based on the second enable signal.

In some examples, the memory device further comprises a plurality of word lines coupled to the plurality of memory cells; in a process of refreshing any one of the memory cells, a turn-on voltage is applied on a word line coupled to the one memory cell;
the initialization process comprises a configuration information storing stage and a word line configuring stage, wherein the word line configuring stage is to load a word line configuring parameter from stored configuration information and configure the plurality of word lines with the word line configuring parameter; and
the plurality of pulse signals are to control the refreshing circuit to perform at least one pass of refreshing on all the memory cells in the memory array before the word line configuring stage starts.

In some examples, the peripheral circuit further comprises a command parsing circuit connected to the refreshing circuit;
the command parsing circuit is configured to parse a refresh command, obtain a control signal corresponding to the refresh command, wherein the refresh command includes a command generated after the initialization process ends and indicating to refresh a target memory cell in the memory array; and the control signal corresponding to the refresh command is to control the refreshing circuit to refresh the target memory cell after the initialization process ends.

According to another aspect, an example of the disclosure provides a memory system, comprising:
the memory device of any one aspect above;
and a controller coupled with the memory device, the controller is configured to control the memory.

According to another aspect, an example of the disclosure provides an electronic system including a host and a memory system coupled to the host, wherein the memory system is the memory system described above.

The above is only an example of the disclosure and shall not be used to restrict the disclosure. Any modification, equivalent replacement, improvement, etc. made within the principles of the disclosure shall be included in the protection of the disclosure.

What is claimed

1. A memory device, comprising:
a memory array comprising a plurality of memory cells; and
a peripheral circuit coupled with the memory array and comprising:
an initialization circuit configured to perform an initialization process of the memory device after the memory device is powered on;
a signal generation circuit configured to generate a refresh control signal and send the refresh control signal to a refresh circuit; and
the refresh circuit configured to perform a first refresh pass on the memory cells in the memory array during the initialization process based on the refresh control signal.

2. The memory device of claim 1, wherein:
the refresh control signal comprises a plurality of pulse signals;
the signal generation circuit comprises a cycle control sub-circuit and a signal generation sub-circuit;
the cycle control sub-circuit is configured to generate a plurality of reference control signals in cycles during the initialization process;
the signal generation sub-circuit is configured to generate ones of the pulse signals based corresponding ones of the reference control signals, and send a first one of the pulse signals to the refresh circuit; and
the refresh circuit is configured to perform a second refresh pass on a portion of the memory cells in the memory array during the initialization process based on the first one of the pulse signals.

3. The memory device of claim 2, wherein:
the signal generation circuit further comprises a logic sub-circuit;
the logic sub-circuit is configured to generate a first enable signal after a reference condition is satisfied during the initialization process;
the satisfied reference condition is to indicate that the pulse signals are not able to perform the first refresh pass on the memory cells in the memory array; and
the cycle control sub-circuit is configured to generate the plurality of reference control signals in cycles based on the first enable signal.

4. The memory device of claim 3, wherein:
the logic sub-circuit is configured to generate a second enable signal when the reference condition is not satisfied; and
the cycle control sub-circuit is configured to stop generating the reference control signals based on the second enable signal.

5. The memory device of claim 1, wherein the peripheral circuit further comprises a component control circuit configured to adjust a reference component from a default state to a state in which a refresh operation is supported, wherein the reference component is to refresh a memory cell of the memory cells.

6. The memory device of claim 5, wherein the component control circuit is configured to restore the reference component from the state in which the refresh operation is supported to the default state.

7. The memory device of claim 6, wherein:
in the default state, power is turned off and reset control is enabled;
in the state in which the refresh operation is supported, the power is turned on and the reset control is disabled;
the reset control is to maintain the reference component in a reset state;
the component control circuit is to restore the reference component from the state in which the refresh operation is supported to the default state based on a first operation and a second operation;
the first operation is to enable the reset control of the reference component;
the second operation is to disconnect a power supply to the reference component; and
a completion time of the first operation is earlier than a start time of the second operation.

8. The memory device of claim 1, wherein:
the memory device further comprises a plurality of word lines coupled to the plurality of memory cells;
in a process to refresh any one of the memory cells, a turn-on voltage is applied on a corresponding one of the word lines coupled to the one of the memory cells;
the initialization process comprises a configuration information storing stage and a word line configuration stage;
the word line configuration stage is to load a word line configuration parameter from stored configuration information and configure the plurality of word lines with the word line configuration parameter; and
the refresh circuit is configured to perform the first refresh pass on the memory cells in the memory array before the word line configuration stage starts based on the refresh control signal.

9. The memory device of claim 1, wherein:
the peripheral circuit further comprises a command parser circuit;
the command parser circuit is configured to parse a refresh command and obtain a control signal corresponding to the refresh command;
the refresh command is generated after the initialization process ends and indicates to refresh a target memory cell in the memory array; and
the refresh circuit is configured to refresh the target memory cell after the initialization process ends based on the control signal.

10. A method for operating a memory device, the method comprising:
performing an initialization process on the memory device after the memory device is powered on;
generating a refresh control signal; and
performing a refresh pass on a plurality of memory cells in a memory array of the memory device during the initialization process based on the refresh control signal.

11. The method of claim 10, wherein the refresh control signal comprises a plurality of pulse signals, the generating of the refresh control signal comprises:
generating a plurality of reference control signals in cycles during the initialization process;
generating a pulse signal based on each reference control signal; and
performing a second refresh pass on a portion of the memory cells in the memory array during the initialization process based on the pulse signal.

12. The method of claim 11, wherein the generating of the plurality of reference control signals in cycles during the initialization process comprises:
generating a first enable signal when a reference condition is satisfied during the initialization process, wherein the satisfied reference condition is to indicate that the pulse signals are not able to perform the refresh pass on the memory cells in the memory array; and
generating the plurality of reference control signals in cycles based on the first enable signal.

13. The method of claim 12, further comprising:
generating a second enable signal when the reference condition is not satisfied; and
stopping the generating of the reference control signals based on the second enable signal.

14. The method of claim 10, further comprising:
adjusting a reference component from a default state to a state in which a refresh operation is supported, wherein the reference component is to be utilized to refresh a memory cell of the memory cells.

15. The method of claim 14, further comprising:
restoring the reference component from the state in which the refresh operation is supported to the default state.

16. The method of claim 15, wherein:
in the default state, power is turned off and reset control is enabled;
in the state in which the refresh operation is supported, the power is turned on and the reset control is disabled;
the reset control is to maintain the reference component in a reset state;
the restoring of the reference component from the state in which the refresh operation is supported to the default state is implemented by performing a first operation and a second operation;
the first operation to enable the reset control of the reference component;
the second operation to disconnect power supply to the reference component; and
a completion time of the first operation is earlier than a start time of the second operation.

17. The method of claim 10, wherein:
the memory device further comprises a plurality of word lines coupled to the plurality of memory cells;
in a process of refreshing any one of the memory cells, applying a turn-on voltage to a corresponding one of the word lines coupled to the one of the memory cells;
the initialization process comprises a configuration information storing stage and a word line configuration stage;
the word line configuration stage is to load a word line configuration parameter from stored configuration information and configure the plurality of word lines with the word line configuration parameter; and
the performing of the refresh pass on the memory cells in the memory array during the initialization process based on the refresh control signal comprises:
performing the refresh pass on the memory cells in the memory array before the word line configuration stage starts based on the refresh control signal.

18. The method of claim 10, further comprising:
parsing a refresh command;
obtaining a control signal corresponding to the refresh command, wherein the refresh command is generated after the initialization process ends and indicates to refresh a target memory cell in the memory array; and
refreshing the target memory cell after the initialization process ends based on the control signal corresponding to the refresh command.

19. A memory device, comprising:
a memory array comprising a plurality of memory cells; and
a peripheral circuit coupled with the memory array, wherein the peripheral circuit comprises a signal generation circuit, an initialization circuit coupled with the signal generation circuit, and a refresh circuit coupled with the signal generation circuit, wherein:
the signal generation circuit comprises a cycle control sub-circuit and a signal generation sub-circuit coupled with the cycle control sub-circuit;
the cycle control sub-circuit is configured to generate a plurality of reference control signals in cycles during an initialization process of the memory device by the initialization circuit; and
the signal generation sub-circuit is configured to generate a plurality of pulse signals based on the plurality of reference control signals, wherein the plurality of pulse signals are to control the refresh circuit to perform a refresh pass on the memory cells in the memory array during the initialization process.

20. The memory device of claim 19, wherein:
the signal generation circuit further comprises a logic sub-circuit connected to the cycle control sub-circuit;
the logic sub-circuit is configured to, during the initialization process, generate a first enable signal when a reference condition is satisfied and to generate a second enable signal when the reference condition is not satisfied;
the satisfied reference condition is to indicate that the pulse signals are not able to perform the refresh pass on the memory cells in the memory array; and
the cycle control sub-circuit is configured to:
generate the plurality of reference control signals in cycles based on the first enable signal; and
stop generating the reference control signals based on the second enable signal.
